(19) United States
(12) Patent Application Publication
(10) Pub. No.: US 2012/0299044 A1
(43) Pub. Date: Nov. 29, 2012

(54) LIGHTING SET, LIGHTING DEVICE, AND DISPLAY DEVICE

(75) Inventor: Hirokazu Mouri, Osaka-shi (JP)

(73) Assignee: SHARP KABUSHIKI KAISHA, Osaka-shi, Osaka (JP)

(21) Appl. No.: 13/576,036

(22) PCT Filed: Feb. 15, 2011
(86) PCT No.: PCT/JP2011/053122

§ 371 Date: Jul. 30, 2012

(30) Foreign Application Priority Data
Feb. 16, 2010 (JP) 2010-030912

(51) Int. Cl. H01L 33/58

(52) U.S. Cl. 257/98; 257/E33.074

(57) ABSTRACT

Disclosed are: a lighting device that stably supplies high-quality surface light; a lighting set that is one part of the lighting device; and a display device equipped with the lighting device. In an LED package (PG), supporting sections (13) cause LED chips (11) to be inclined with respect to the bottom surface (41B) of a backlight chassis (41).

### TECHNICAL FIELD

The present invention is related to a lighting set, a lighting device (such as a backlight unit) equipped with the lighting set, and a display device (such as a liquid crystal display device) equipped with the lighting device.

### BACKGROUND ART

Among display devices equipped with a display panel, one that is equipped with a liquid crystal display panel, which does not emit light by itself, typically requires a backlight unit which is capable of supplying planar light to the liquid crystal display panel. For example, a liquid crystal display device disclosed in Patent Literature 1 is equipped with such a backlight unit as illustrated in FIG. 22.

In the backlight unit 149 illustrated in FIG. 22, LEDs 111, which are each a light emitting element including a light emitting diode (LED) chip as a light emitting chip, are laid all over a mounting board 121 which is placed on a backlight chassis 141 which is a base plate. A light guide plate 181 is so arranged as to cover the LEDs 111. The light guide plate 181 is provided with diffusion plates 143 which are fitted to an LEDs 111-side surface of the light guide plate 181 and which are each slightly larger than an outline of each of the LEDs 111, in other words, a circumference of each of the LEDs 111. More specifically, the diffusion plates 143 are each arranged right above a corresponding one of the LEDs 111 in a superposed manner.

With this configuration, light from the LEDs 111 is diffused inside the diffusion plates 143, then enters the light guide plate 181, and further undergoes multiple reflection inside the light guide plate 181, whereby planar light is generated. That is, the backlight 149 does not allow the light from the LEDs 111 to pass through the light guide plate 181 straight and reach a liquid crystal display panel. This helps reduce the possibility of the planar light including high-brightness portions. In other words, the planar light is less prone to uneven distribution of light quantity.

### CITATION LIST

### Patent Literature

Patent Literature 1: JP-A-2005-249942

### SUMMARY OF INVENTION

### Technical Problem

With the backlight unit 149 disclosed in Patent Literature 1, it is difficult to adjust positions of the diffusion plates 143 fitted to the light guide plate 181 and the LEDs 111. The adjustment is so difficult that it is not achieved in many cases. Vibration applied to a liquid crystal display device 169 sometimes causes misalignment between the diffusion plates 143 and the LEDs 111. Thus, with the backlight unit 149 disclosed in Patent Literature 1, misalignment between the diffusion plates 143 and the LEDs 111 tends to prevent generation of high-quality planar light (backlight light).

The present invention has been made in view of the foregoing, and a principal object thereof is to provide a lighting device which stably supplies high-quality planar light, a lighting set as part of the lighting device, and further, a display device equipped with such a lighting device.

### Solution to Problem

According to an aspect of the present invention, a lighting set includes a light source package having a light emitting chip and a support portion on which the light emitting chip is supported, a mounting board on which the light source package is supported in either one of a direct manner and an indirect manner, and a base plate on which the mounting board is supported in either one of a direct manner and an indirect manner. The lighting set further includes a correction portion which causes the light emitting chip to be inclined to thereby cause a maximum-light-intensity axis, along which light from the light source package has maximum light intensity, to be inclined with respect to the base plate.

According to an embodiment of the present invention, in the lighting set configured as described above, it is preferable that, in a case in which the light source package is supported directly on the mounting board and the mounting board is supported directly on the base plate, the support portion serve as the correction portion. The support portion is preferably built as a block having a support portion top surface which is in contact with the light emitting chip and a support portion bottom surface which is in contact with the base plate, the support portion top surface and the support portion bottom surface extending in crossing directions.

According to an embodiment of the present invention, in the lighting set configured as described above, it is preferable that, in a case in which the light source package is supported indirectly on the mounting board and the mounting board is supported directly on the base plate, a connection stand provided interposed between the support portion and the mounting board serve as the correction portion. The connection stand is preferably built as a block having a connection stand top surface which is in contact with the support portion and the connection stand bottom surface which is in contact with the mounting board, the connection stand top surface and the connection stand bottom surface extending in crossing directions.

According to an embodiment of the present invention, in the lighting set configured as described above, it is preferable that, in a case in which the light source package is supported directly on the mounting board and the mounting board is supported indirectly on the base plate, a holding stand provided interposed between the mounting board and the base plate serve as the correction portion. The holding stand is preferably built as a block having a holding stand top surface which is in contact with the mounting board and a holding stand bottom surface which is in contact with the base plate, the holding stand top surface and the holding stand bottom surface extending in crossing directions.

In the lighting set, the maximum-light-intensity axis is inclined to cause light from the light source package to be inclined with respect to the base plate. With this configuration, if the lighting set is used in, for example, a lighting device such as a backlight unit, it is easy for light from the lighting set to be obliquely incident on an irradiation target, such as a diffusion plate incorporated in the lighting device, which receives light from the lighting set.

A contour of a light beam reaching the irradiation target in the above-described manner extends over a wider area than a contour of a light beam perpendicularly incident on the irradiation target. Then, if a plurality of light source packages capable of making light obliquely incident on the irradiation target are arranged in the lighting set, the light beams from the light source packages reaching the irradiation target mix with each other at a high rate. In other words, the light beams overlap with each other over a larger area. As a result, in a case in which planar light is generated by the light beams from the plurality of light source packages which mix with each other, the planar light includes no dark region which would appear if the light beams were separated from each other. This helps achieve stable generation of planar light which suffers less from uneven distribution of light quantity which would otherwise be caused by such dark regions.

The present invention also includes a lighting device which includes the lighting set configured as described above and a diffusion plate which receives light from the lighting set, and in which a minimum angle of the maximum-light-intensity axis with respect to the diffusion plate is smaller than 90°.

According to an embodiment of the present invention, in the lighting device configured as described above, for the light beams to overlap with each other over a larger area, it is preferable that the lighting device satisfy the following conditional expression (1).

W≦H×{tan(δ+θ)−tan(δ−θ)} conditional expression (1)

where

W represents arrangement interval for the light source package;

H represents minimum distance from a light emitting point in the light source package to the diffusion plate;

δ represents angle that a light emitting surface of the light emitting chip has with respect to the base plate, in a plane where a locus of movement of the maximum-light-intensity axis resulting from inclination of the light source package is able to be grasped as a plane; and

θ represents angle formed, in the plane where the locus of movement of the maximum-light-intensity axis resulting from inclination of the light source package is able to be grasped as a plane, by the maximum-light-intensity axis and one portion of peripheral portions of light from the light source package which surround the maximum-light-intensity axis, the one portion being inclined to be the closest to the base plate of all the peripheral portions of the light from the light source package.

According to an embodiment of the present invention, in the lighting device configured as described above, for the light beams to overlap with each other over a still larger area, it is preferable that the lighting device satisfy the following conditional expression (2).

W≦H×tan δ conditional expression (2)

where

W represents arrangement interval for the light source package

H represents minimum distance from a light emitting point in the light source package to the diffusion plate; and

δ represents angle that a light emitting surface of the light emitting chip has with respect to the base plate, in a plane where a locus of movement of the maximum-light-intensity axis resulting from inclination of the light source package is able to be grasped as a plane.

According to an embodiment of the present invention, in the lighting device configured as described above, it is preferable that, assuming that light intensity corresponding to the maximum-light-intensity axis is 100% light intensity, light intensity of the peripheral portions of the light from the light source package be not higher than 30% of the light intensity corresponding to the maximum-light-intensity axis. Alternatively, it is preferable that the light intensity of the peripheral portions of the light from the light source package be not higher than 50% of the light intensity corresponding to the maximum-light-intensity axis.

According to another aspect of the present invention, a lighting set includes a light source package which has a light emitting chip, a support portion on which the light emitting chip is supported, and a sealing member which seals the light emitting chip, a mounting board on which the light source package is supported in either one of a direct manner and an indirect manner; and a base plate on which the mounting board is supported in either one of a direct manner and an indirect manner. In the lighting set, the sealing member transmits light and has an optical surface. By using the optical surface, the sealing member functions as a correction portion which causes a maximum-light-intensity axis, along which light passing through the sealing member has maximum light intensity, to be inclined with respect to the base plate.

According to an embodiment of the present invention, in the lighting set configured as described above, the optical surface and the light emitting chip are preferably positioned eccentric to each other. Alternatively, the sealing member may function as a Fresnel lens. Still alternatively, the optical surface may include a portion having a curvature that is different in curvature from the other portions of the optical surface. Still alternatively, a portion of the optical surface located right above the light emitting chip may be depressed in comparison with portions therearound. With the lighting set configured as just described here, it is possible to cause the maximum-light-intensity axis to be inclined, by making use of the shape of the sealing member, and as a result, light from the light source package travels obliquely with respect to the base plate.

According to an embodiment of the present invention, in the lighting set configured as described above, it is preferable that, in a case in which the light source package is supported directly on the mounting board and the mounting board is supported directly on the base plate, it is preferable that the support portion function as the following correction portion. That is, it is preferable that the support portion be built as a block having a support portion top surface which is in contact with the light emitting chip and a support portion bottom surface which is in contact with the base plate, and that the support portion function as the correction portion which causes a maximum-light-intensity axis, along which light passing through the sealing member has maximum light intensity, to be inclined with respect to the base plate.

According to an embodiment of the present invention, in the lighting set configured as described above, it is preferable that, in a case in which the light source package is supported indirectly on the mounting board and the mounting board is supported directly on the base plate, it is preferable that a connection stand provided interposed between the support portion and the mounting board serve as the correction portion. It is preferable that the connection stand be built as a block having a connection stand top surface which is in contact with the support portion and a connection stand bottom surface which is in contact with the mounting board, the connection stand top surface and the connection stand bottom surface extending in crossing directions, and that the connection stand function as the correction portion which causes a maximum-light-intensity axis, along which light passing through the sealing member has maximum light intensity, to be inclined with respect to the base plate.

According to an embodiment of the present invention, in the lighting set configured as described above, it is preferable that, in a case in which the light source package is supported directly on the mounting board and the mounting board is supported indirectly on the base plate, a holding stand provided interposed between the mounting board and the base plate function as the correction portion. It is preferable that the holding stand be built as a block having a holding stand top surface which is in contact with the mounting board and a holding stand bottom surface which is in contact with the base plate, the holding stand top surface and the holding stand bottom surface extending in crossing directions, and that the holding stand function as the correction portion which causes a maximum-light-intensity axis, along which light passing through the sealing member has maximum light intensity, to be inclined with respect to the base plate.

The present invention also includes a lighting device that includes the lighting set configured as described above and a diffusion plate which receives light from the lighting set, and in which a minimum angle of the maximum-light-intensity axis with respect to the diffusion plate is smaller than 90°.

According to an embodiment of the present invention, a lighting device may be configured to include a lighting set which includes a sealing member having a portion depressed in comparison with portions therearound and a diffusion plate which receives light from the lighting set. It is preferable that the lighting device satisfy the following conditional expression (3).

W≦H×tan(γ1) conditional expression (3)

where

W represents arrangement interval for the light source package

H represents minimum distance from a light emitting point in the light source package to the diffusion plate; and

γ1 represents, assuming that the maximum light intensity of light passing through the sealing member is 100% light intensity and that an angle of the direction directly upward from the light emitting chip is 0°, an angle of one portion of 70%-light-intensity portions of the light passing through the sealing member, the one portion being the most diverged of all the 70%-light-intensity portions from the direction directly upward from the light emitting chip, with respect to the direction directly upward from the light emitting chip, in a cross-section taken along a light-source-package arrangement direction.

According to an embodiment of the present invention, a lighting device may be configured to include a lighting set which includes a sealing member having a portion depressed in comparison with portions therearound, and a diffusion plate which receives light from the lighting set. It is preferable that the lighting device satisfy the following conditional expression (4).

W≦H×tan(φ) conditional expression (4)

where

W represents arrangement interval for the light source package

H represents minimum distance from a light emitting point in the light source package to the diffusion plate; and

φ represents, assuming that an angle of the direction directly upward from the light emitting chip is 0°, an angle that the maximum-light-intensity axis, along which the light passing through the sealing member has the maximum light intensity, has with respect to the direction directly upward from the light emitting chip, in a cross-section taken along a light-source-package arrangement direction.

The present invention also includes a display device that includes the lighting device configured as described above and a display panel which receives light from the lighting device. The present invention also includes a display device in which the display panel is a liquid crystal display panel.

### Advantageous Effects of Invention

According to a lighting set of the present invention, a light source package is caused to emit light obliquely with respect to a base plate, and thus a light beam covers a large area when it reaches an irradiation target. Thus, a lighting set having a plurality of light source packages does not allow areas on the irradiation target that are covered by light beams to separate from each other, but on the contrary, causes the areas to overlap with each other over a larger area, and thus, the lighting set is capable of stably generating high-quality planar light (which, for example, does not include uneven distribution of light quantity).

### BRIEF DESCRIPTION OF DRAWINGS

FIG. 1 A sectional view illustrating the liquid crystal display device (Example 1) of FIG. 2, taken along line A-A′ and seen as indicated by arrows in FIG. 2;

FIG. 2 An exploded perspective view of the liquid crystal display device (Example 1);

FIG. 3 A diagram illustrating a directional pattern of light from an LED package (in particular, an LED chip);

FIG. 4 A perspective view of an LED package, a mounting board, and a backlight chassis in the liquid crystal display device (Example 1);

FIG. 5 A comparative diagram for comparison between two types of LED packages arranged at different angles;

FIG. 6 An enlarged sectional view for describing an arrangement interval for LED packages;

FIG. 7 A sectional view of a liquid crystal display device (Example 2);

FIG. 8 A perspective view of an LED package, a connection stand, a mounting board, and a backlight chassis in the liquid crystal display device (Example 2);

FIG. 9 A sectional view illustrating a liquid crystal display device (Example 3) illustrated in FIG. 10, taken along line B-B′ and seen as indicated by arrows in FIG. 10;

FIG. 10 An exploded perspective view of the liquid crystal display device (Example 3);

FIG. 11 A perspective view of an LED package, a mounting board, and a backlight chassis in the liquid crystal display device (Example 3);

FIG. 12 A perspective view of an LED package, a mounting board, and a backlight chassis in a liquid crystal display device (Example 4);

FIG. 13 A sectional view of the liquid crystal display device (Example 4);

FIG. 14 A sectional view of a liquid crystal display device (Example 5);

FIG. 15 A sectional view of a liquid crystal display device (Example 6);

FIG. 16 A perspective view of an LED package, a mounting board, and a backlight chassis in a liquid crystal display device (Example 7);

FIG. 17 A diagram illustrating a directional pattern of light from a sealing member;

FIG. 18 A sectional view of the liquid crystal display device (Example 7);

FIG. 19 An enlarged sectional view for describing an arrangement interval for LED packages;

FIG. 20A A sectional view of a liquid crystal display device (Example 8);

FIG. 20B A sectional view of a liquid crystal display device (Example 9);

FIG. 20C A sectional view of a liquid crystal display device (Example 10);

FIG. 21 An exploded perspective view of a liquid crystal television set; and

FIG. 22 A sectional view of a conventional backlight unit.

### DESCRIPTION OF EMBODIMENTS

### Embodiment 1

Hereinafter, descriptions will be given of embodiments of the present invention with reference to the accompanying drawings. Hatching and reference signs for members may sometimes be omitted in a drawing for ease of description, and in such a case, a different drawing is to be referred to. Numbers and values here are merely examples, and do not limit the present invention in any way.

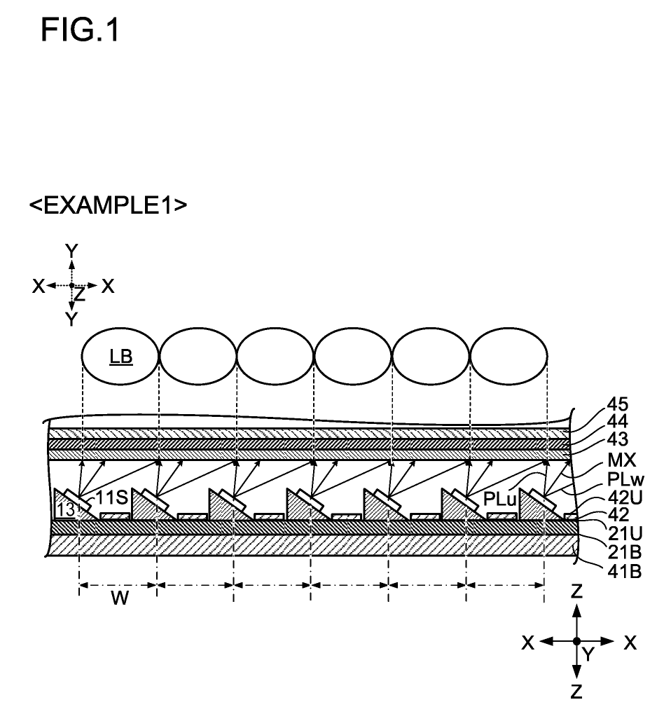

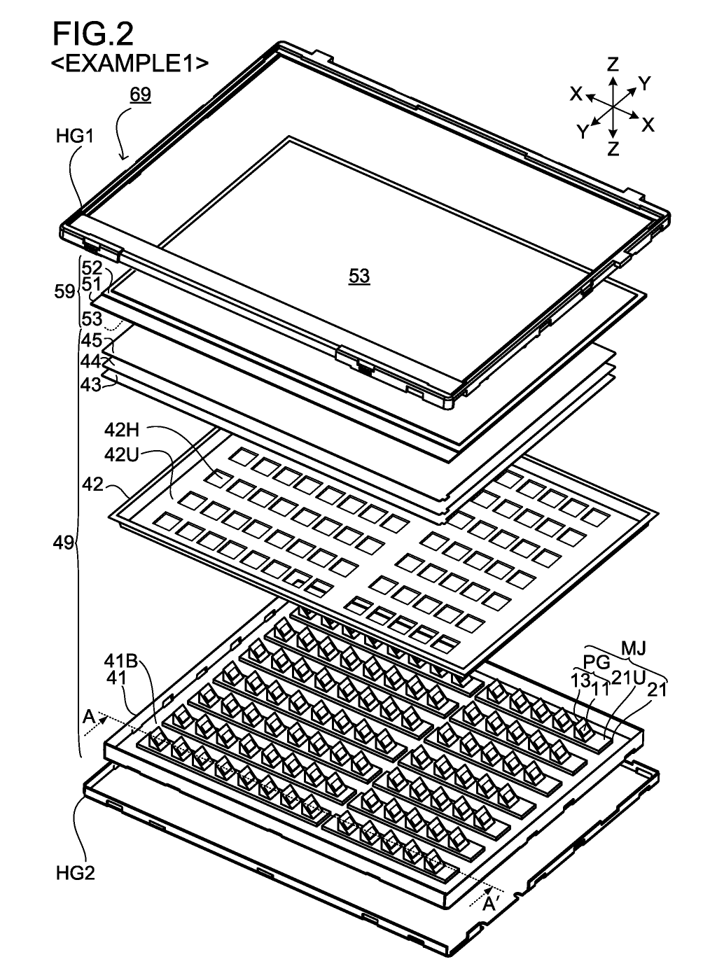

FIG. 21 is an exploded perspective view of a liquid crystal television set 79 equipped with a liquid crystal display device 69 which is a display device. The liquid crystal television set 79 is a television receiver which receives television broadcast signals and displays images. FIG. 2 is an exploded perspective view of the liquid crystal display device 69 which is incorporated in the liquid crystal television set 79. FIG. 1 is a sectional view of the liquid crystal display device 69 of FIG. 2, taken along line A-A′ and seen as indicated by arrows in FIG. 2. The liquid crystal display device 69 and the like illustrated in FIGS. 1 and 2 constitute Example 1.

As illustrated in FIG. 2, the liquid crystal display device 69 includes a liquid crystal display panel 59 as a display panel, a backlight unit 49 as a lighting device which supplies light to the liquid crystal display panel 59, and a housing HG in which these components are held. The housing HG is composed of a front housing HG1 and a rear housing HG2.

The liquid crystal display panel 59 is configured by fitting an active matrix substrate 51 including switching elements such as thin film transistors (TFT) and a counter substrate 52 which faces the active matrix substrate 51 to each other with a seal material (not shown). Liquid crystal (not shown) is provided in a space between the two substrates 51 and 52.

A polarization film 53 is provided on each of a light receiving side of the active matrix substrate 51 and a light exit side of the counter substrate 52. The thus configured liquid crystal display panel 59 makes use of variation in transmittance attributable to inclination of liquid crystal molecules to display images.

Next, a description will be given of the backlight unit 49 which is positioned directly under the liquid crystal display panel 59. The backlight unit 49 includes LED modules MJ as light source modules, a backlight chassis 41, a reflection sheet 42, a diffusion plate 43, a prism sheet 44, and a diffusion sheet 45.

The LED modules MJ each includes, as illustrated in the perspective view of FIG. 2, an LED package PG as a light source package and a mounting board 21. The LED package PG includes an LED chip 11 as a light emitting chip and a support portion 13. A set including the LED package PG, the mounting board 21, and the later-described backlight chassis 41, specifically a bottom surface 41B thereof, will sometimes be referred to as a lighting set.

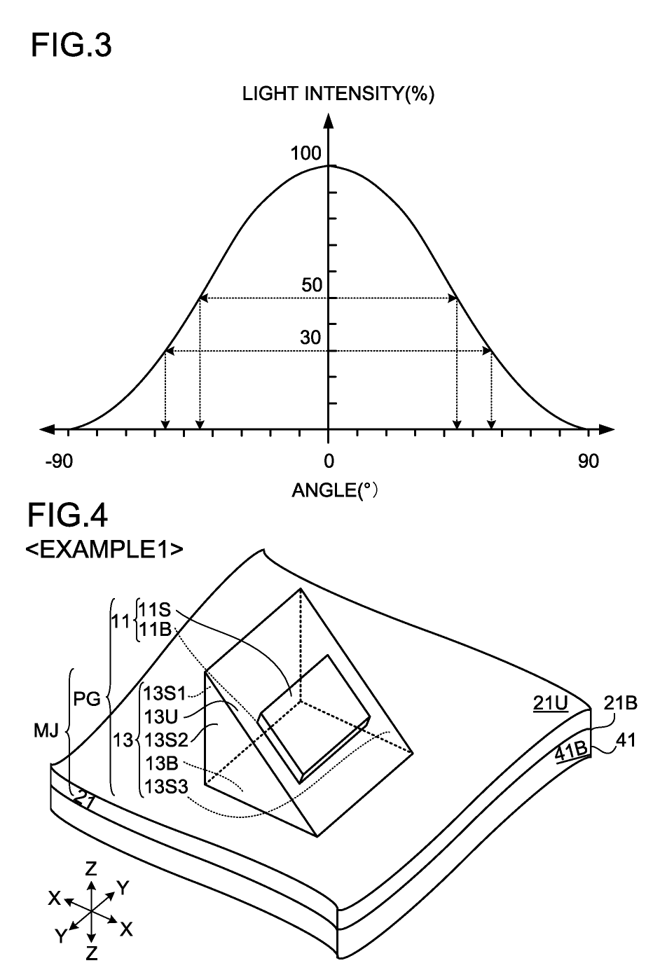

The light emitting diode (LED) chip 11, which is a chip of a light emitting element, serves as a light source. As illustrated in the directional pattern diagram of FIG. 3, light emitted from the LED chip 11 is most intense in a direction that is substantially perpendicular to a light emitting surface 11S of the LED chip 11. In FIG. 3, a direction directly upward from the light emitting surface 11S of the LED chip 11 is the reference direction which corresponds to an angle of 0°, the axis of abscissas indicates an angle of light with respect to the direction directly upward from the light emitting surface 11S, and the axis of ordinates indicates intensity of light. The direction in which the light from the LED chip 11, and thus the light from the LED package PG, is most intense will be referred to as a maximum-light-intensity axis MX.

The support portion 13 is a stand for supporting the LED chip 11. The support portion 13 includes an unillustrated conductor, and the LED chip 11 is electrically connected to the conductor included in the support portion 13 via a conductor which is not illustrated, either. The support portion 13 is supported on a mounting surface 21U of the mounting board 21, and the conductor of the support portion 13 is electrically connected to an unillustrated conductor of the mounting board 21. Thereby, the LED chip 11 is supplied with electric power to emit light.

As shown in FIG. 4 (which is a perspective view illustrating the LED package PG, the mounting board 21, and the backlight chassis 41), a bottom surface 11B of the LED chip 11, which is opposite from the light emitting surface 11S of the LED chip 11, is fitted to the support portion 13, and thereby, the LED chip 11 is disposed on the support portion 13. One surface of the support portion 13 that is in contact with the LED chip 11 will be referred to as a support portion top surface 13U, and another surface of the support portion 13 that is in contact with the mounting board 21 will be referred to as a support portion bottom surface 13B.

The mounting board 21 has a rectangular shape and includes a conductor for passing electric current from an unillustrated power supply. The mounting board 21 supports a plurality of LED packages PG on the mounting surface 21U thereof and is electrically connected to the LED packages PG. The number of the LED packages PG mounted on the mounting board 21 is not limited to two or more, and a single LED package may be mounted the mounting board 21.

On the mounting surface 21U of the mounting board 21, there is provided a resist film (not illustrated) which serves as a protection film. One surface that is opposite from the mounting surface 21U on which the LED packages PG are supported will be referred to as a back surface 21B. There is no particular limitation to the resist film, but it is preferable that the color of the resist film be white, which has a high reflectance. A white resist film would help eliminate one of the causes of uneven distribution of light quantity, that is, absorption of light by the mounting board 21, because light reaching the white resist film is reflected outward.

The backlight unit 49 illustrated in FIG. 2 is equipped with comparatively short mounting boards 21 on each of which five LED packages PG are arranged in a row and comparatively long mounting boards 21 on each of which eight LED packages PG are arranged in a row.

These two kinds of mounting boards 21 are aligned such that the five LED packages PG and the eight LED packages PG together form a row of thirteen LED packages PG. The two kinds of mounting boards 21 are also aligned in a direction that crosses (perpendicularly, for example) the direction in which the thirteen LED packages PG are aligned. Intervals W at which the LED packages PG are arranged do not necessarily need to be equal; they are so adjusted to give the lighting device the optimum brightness distribution.

According to this configuration, the LED packages PG are arranged in matrix. In other words, the LED modules MJ are planarly arranged. With this arrangement, planar light is generated by mixing light from the LED packages PG. Here, the direction in which the two different kinds of mounting boards 21 are arranged will be referred to as direction X, the direction in which the same kinds of mounting boards 21 are arranged will be referred to as direction Y, and the direction that perpendicularly crosses directions X and Y will be referred to as direction Z.

As shown in FIG. 2, the backlight chassis 41 is a box-like member, in which the plurality of LED modules MJ are placed by being laid over the bottom surface 41B which serves as a base plate. The mounting boards 21 of the LED modules MJ are fastened to the bottom surface 41B of the backlight chassis 41 with unillustrated rivets.

The bottom surface 41B of the backlight chassis 41 may be provided with a support pin for supporting the diffusion plate 43, the prism sheet 44, and the diffusion sheet 45. In that case, the backlight chassis 41 supports, with tops of its own side walls and the support pin, the diffusion plate 43, the prism sheet 44, and the diffusion sheet 45 which are laid one on another in this order. The diffusion plate 43 and its accompaniments are laid parallel to the bottom surface 41B.

The reflection sheet 42, which is an optical sheet, has a reflection surface 42U, and covers the plurality of LED packages PG with a back side of the reflection surface 42U facing them. The reflection sheet 42 includes through holes 42H located corresponding to the positions of the LED packages PG, and via the through holes 42H, the LED packages PG are exposed to the reflection surface 42U side. The reflection sheet 42 is preferably provided with through holes for exposing the rivets and the support pin.

With this configuration, even if part of light from the LED packages PG travels toward the bottom surface 41B of the backlight chassis 41, the part of the light is reflected by the reflection surface 42U of the reflection sheet 42 to travel diverging from the bottom surface 41B. In this way, the presence of the reflection sheet 42 enables the light from the LED packages PG to travel toward the diffusion plate 43, which faces the reflection surface 42U, without loss. In FIGS. 4 to 6, the reflection sheet 42 is omitted. The reflection sheet 42 is preferably made of a material having a comparatively high reflectivity.

The diffusion plate 43, which is an optical sheet, is superimposed on the reflection sheet 42, and diffuses light emitted from the LED modules MJ and light reflected from the reflection sheet 42U. That is, the diffusion plate 43 diffuses light generated by the plurality of LED modules MJ, or, by the plurality of LED modules MJ arranged in matrix, to thereby distribute the light all across the liquid crystal display panel 59. The diffusion plate 43 is preferably made of a material internal part of which has a high diffusibility while a surface of which light from the LED chips 11 reaches first has a high reflectance.

The prism sheet 44, which is an optical sheet, is superimposed on the diffusion plate 43. The prism sheet 44 has a configuration in which a plurality of prisms which linearly extend in one direction and have, for example, a triangular sectional shape are arranged on a sheet surface. The prism sheet 44 deflects a radiation characteristic of light from the diffusion plate 43. The direction in which the prisms are arranged to extend is selected from directions X and Y as necessary.

The diffusion sheet 45, which is an optical sheet, is superimposed on the prism sheet 44. Fine particles that refract and diffuse light are dispersed inside the diffusion sheet 45. The diffusion sheet 45 prevents light from the prism sheet 44 from gathering on a limited part, to thereby reduce difference between bright and dark parts, that is, uneven distribution of light quantity. The diffusion plate 43, the prism sheet 44, and the diffusion sheet 45 are presented as optical sheets, but the types and the number of optical sheets are not limited to those presented above, and various options are possible.

The backlight unit 49 having the above-described configuration makes the planar light generated by the plurality of LED modules MJ pass through the plurality of optical sheets 43 to 45, and supplies the planar light to the liquid crystal display panel 59. Thereby, the liquid crystal display panel 59, which does not emit light itself, receives light from the backlight unit 49, which is backlight light, and thereby exerts an enhanced display function.

A description will now be given of the support portion 13 included in each of the LED packages PG, with reference to FIGS. 1 to 4. As illustrated in FIG. 4, the substantially planar back surface 21B of the mounting board 21, that is, the surface 21B that parallelly faces the substantially planar mounting surface 21U, is in tight contact with the substantially planar bottom surface 41B of the backlight chassis 41. The support portion bottom surface 13B of the support portion 13 is in tight contact with the mounting surface 21U of the mounting board 21. The support portion bottom surface 13B is also substantially planar. The support portion 13 is built as a block having five surfaces in total, namely, the support portion bottom surface 13B, the support portion top surface 13U on which the LED chip 11 is supported, and in addition, three support portion side surfaces 13S1 to 13S3 that extend rising from the support portion bottom surface 13B.

The support portion 13, which is built as a block, is configured such that the support portion top surface 13U thereof is not parallel but inclined with respect to the support portion bottom surface 13B thereof, in other words, with respect to the mounting surface of the mounting board 21, or, the bottom surface 41B of the backlight chassis 41. That is, the support portion 13 is built as a block that is disposed such that the support portion top surface 13U and the support portion bottom surface 13B extend in a direction in which they cross each other. Thus, light emitted from the LED chip 11, that is, light emitted from the LED package PG, especially a portion of the light corresponding to the maximum-light-intensity axis MX, travels along a path inclined with respect to the bottom surface 41B of the backlight chassis 41, to be obliquely incident on the diffusion plate 43, which is positioned parallel to the bottom surface 41B of the backlight chassis 41.

If the maximum-light-intensity axis MX, along which the light from the LED package PG is most intense, is inclined with respect to the diffusion plate 43 as described above, light beams LB that reach the diffusion plate 43 tend to have an oval shape as conceptually illustrated in FIG. 1. Signs X, Y, and Z associated with dotted-line arrows in the figure indicate positional relationship of the light beams LB (this applies to the other drawings as well).

The oval shape of each of the light beams LB results from the fact that peripheral light PLw, which is a portion of the light beam LB travelling on a side close to the bottom surface 41B of the backlight chassis 41, travels a longer optical path to the diffusion plate 43 than peripheral light PLu, which is a portion of the light beam LB travelling on a side away from the bottom surface 41B. Here, the peripheral light is a portion of the light beam LB that travels on a side of the light beam LB comparatively away from the maximum-light-intensity axis MX (for example, close to an outermost part of the light beam LB).

Comparison will be performed between a case in which the light emitting surface 11S of the LED chip 11 is inclined with respect to the bottom surface 41B and a case in which the light emitting surface 11S of the LED chip 11 is parallel with respect to the bottom surface 41B, the LED chip 11 being placed inside the backlight unit 49 in which space between the diffusion plate 43 and the bottom surface 41B of the backlight chassis 41 is limited as shown in FIG. 1. Here, length of the maximum-light-intensity axis MX from the diffusion plate 43 to the LED chip 11 is the same in both cases.

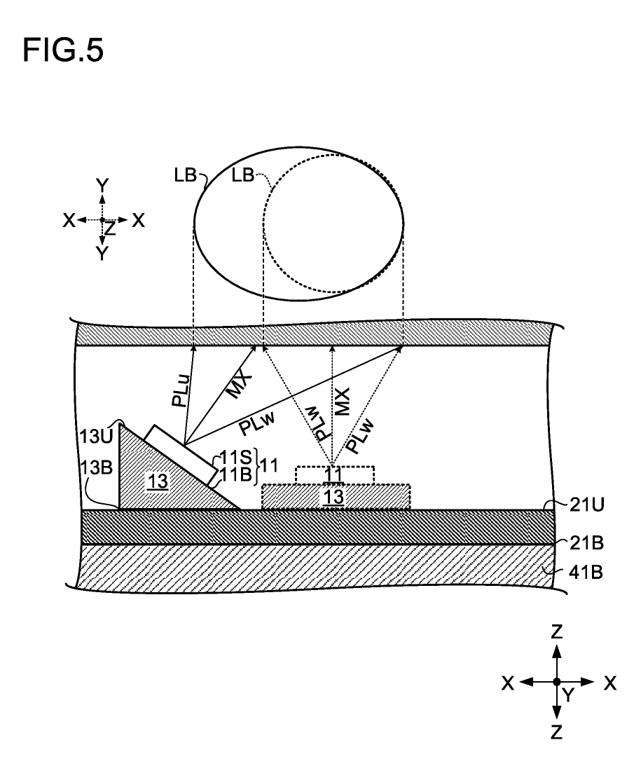

As illustrated in the comparative diagram of FIG. 5, the peripheral light PLw, for example, of peripheral light PL included in the light beam LB travels along an optical path that is inclined with respect to a direction perpendicular to the bottom surface 41B to be the closest to the bottom surface 41B among all portions of the light beam LB, and the peripheral light PLw has an optical path length as described below. That is, the optical path of the peripheral light PLw is longer in the LED chip 11 whose light emitting surface 11S is inclined with respect to the bottom surface 41B than in the LED chip 11 whose light emitting surface 11S is parallel with respect to the bottom surface 41B. As a result, the light beam LB reaching the diffusion plate 43 tends to have an oval shape as conceptually illustrated in FIG. 1. The oval shape of the light beam LB is larger in area than a complete circle shape that the light beam LB has in the case in which the light emitting surface 11S of the LED chip 11 is parallel to the bottom surface 41B.

With this structure, when light from the LED packages PG reaches the diffusion plate 43, the light beams LB of the light are more likely to overlap with each other than separate from each other. This helps reduce the number of regions in the diffusion plate 43 that receive none of the light beams LB. In other words, the diffusion plate 43 includes a smaller number of regions that receive none of the light beams LB and thus are darker than the other regions which receive the light beams LB; that is, the number of dark regions is reduced. Consequently, light from the backlight 49 does not suffer from uneven distribution of light quantity which would otherwise be caused by the dark regions. That is, the backlight 49 stably supplies high-quality light that is free from uneven distribution of light quantity. As a result, quality of images displayed by the liquid crystal display panel 59 that receives the backlight light is improved, and the liquid crystal display device 69 is completed as a display device that is capable of providing high-quality images.

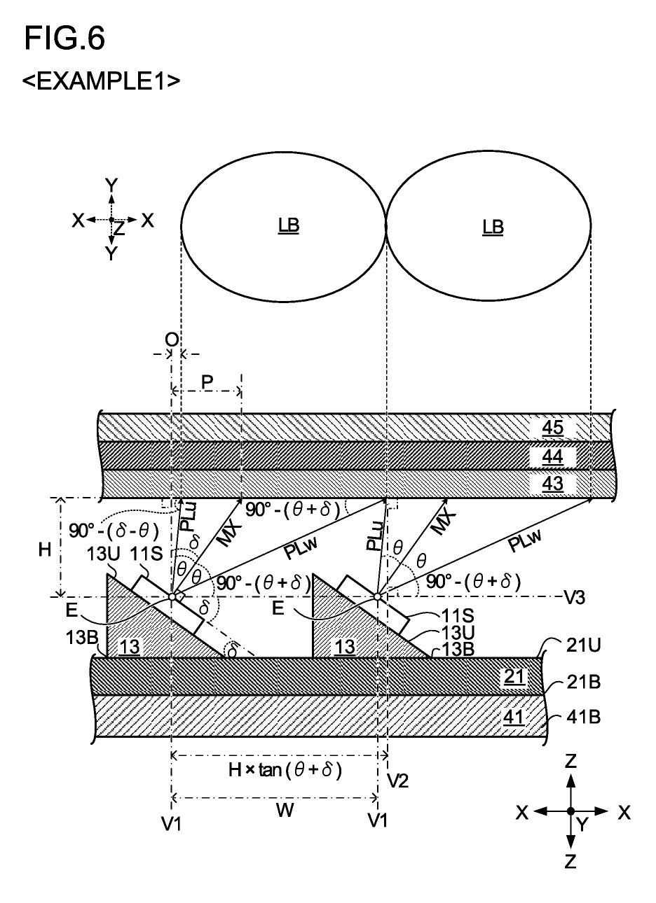

To prevent dark regions from appearing in the diffusion plate 43, it is preferable that the light beams from the LED packages abut with each other without being separated from each other at the diffusion plate 43. Now, with reference to FIG. 6, which is a diagram obtained by enlarging the sectional view of FIG. 1, a description will be given to illustrate that, if the following conditional expression (1) is satisfied, dark regions are prevented from appearing, in other words, the light beams LB abut with each other without being separated from each other at the diffusion plate 43.

W≦H×{tan(δ+θ)−tan(δ−θ)} conditional expression (1)

where

W represents arrangement interval for the LED packages PG;

H represents minimum distance from a light emitting point E in each of the LED packages PG to the diffusion plate 43;

δ represents angle that the light emitting surface 11S of each of the LED chips 11 has with respect to the bottom surface 41B of the backlight chassis 41, in a plane where a locus of movement of the maximum-light-intensity axis MX resulting from the inclination of each of the LED packages PG can be grasped as a plane (for example, a cross-section such as an XZ section which is taken along a direction in which the LED chips 11 are aligned); and

θ represents angle formed, in the plane where the locus of movement of the maximum-light-intensity axis MX resulting from the inclination of each of the LED packages PG can be grasped as a plane, by the maximum-light-intensity axis MX and the peripheral light PLw that is inclined to be the closest to the bottom surface 41B among all portions of the peripheral light of the light from each of the LED packages PG surrounding the maximum-light-intensity axis MX (note that an angle formed by the maximum-light-intensity axis MX and the peripheral light PLu is also “θ”).

Considering two light emitting points E, virtual lines V1 are assumed to extend one from each of the two light emitting points E in a direction perpendicular to the bottom surface 41B of the backlight chassis 41 and the diffusion plate 43. Furthermore, a virtual line V2 is assumed to extend, in the direction perpendicular to the bottom surface 41B of the backlight chassis 41 and the diffusion plate 43, from a point in the diffusion plate 43 that receives a portion of the peripheral light PL that travels from one light emitting point E toward the other light emitting point E, that is, the peripheral light PLw which travels along an optical path inclined from the direction perpendicular to the bottom surface 41B toward the bottom surface 41B to be the closest to the bottom surface 41B among all portions of the peripheral light PL. Moreover, a virtual line V3, which connects the two light emitting points E, is assumed to extend parallel to the bottom surface 41B of the backlight chassis 41 and the diffusion plate 43.

Since the virtual line V3 is parallel to the bottom surface 41B of the backlight chassis 41, an angle formed by the virtual line V3 and the light emitting surface 11S of each of the LED chips 11 is “δ”. If an angle formed by the maximum-light-intensity axis MX extending from one light emitting point E and the light emitting surface 11S including the one light emitting point E is “90°”, an angle formed by the peripheral light PLw and the virtual line V3 is “90°−(θ+δ)”. Since the virtual line V3 and the diffusion plate 43 are parallel to each other, an angle formed by the peripheral light PLw and the diffusion plate 43 is also “90°−(θ+δ)”.

If a shape defined by the peripheral light PLw, one of the virtual lines V1, and the diffusion plate 43 is a right angled triangle having a right angle formed by the virtual line V1 and the diffusion plate 43, since an angle formed by the peripheral light PLw and the virtual line V3 is “90°−(θ+δ)”, a minimum distance between the virtual line V1 and the virtual line V2, which are parallel to each other, is “H×tan(θ+δ)”, where H represents minimum distance from the light emitting point E of each of the LED packages PG to the diffusion plate 43.

A width of the light beam LB can be obtained from the distance “H×tan(θ+δ)” by subtracting a minimum distance O between the virtual line V1 and a point in the diffusion plate 43 that receives the peripheral light PLu from “H×tan(θ+δ)”. If a shape defined by the peripheral light PLu, the virtual line V1, and the diffusion plate 43 is a right angled triangle having a right angle formed by the virtual line V1 and the diffusion plate 43, since an angle formed by the peripheral light PLw and the virtual line V3 is “90°−(θ+δ)”, the distance O is “H×tan(θ−δ)”, where H represents minimum distance from the light emitting point E of each of the LED packages PG to the diffusion plate 43. As a result, the width of the light beam LB is “H×tan(θ+δ)−H×tan(θ−δ)”.

If, at the diffusion plate 43, the light beams LB are not separate from each other but in tight contact with each other, or, if they abut with each other, as conceptually illustrated in FIG. 6, appearance of dark regions is reduced. Thus, it is preferable that the arrangement interval W of the LED packages PG, that is, the minimum distance from one of the virtual lines V1 corresponding to one of the light emitting points E and the other one of the virtual lines V1 corresponding to the other one of the light emitting points E be shorter than the width of the light beams LB, in other words, a light beam diameter. As a result, the conditional expression (1) is introduced.

To surely reduce the appearance of dark regions, the interval W at which the LED packages PG are arranged is preferably equal to or shorter than a distance P between one of the virtual lines V1 corresponding to one of the light emitting points E and a point at which the maximum-light-intensity axis MX crosses the diffusion plate 43 (see FIG. 6). Specifically, it is preferable that the following conditional expression (2) be satisfied.

W≦H×tan δ conditional expression (2)

The conditional expression (2) is obtained based on the fact that a shape defined by the maximum-light-intensity axis MX, the diffusion plate 43, and one of the virtual lines V1 is a right angled triangle having a right angle formed by the virtual line V1 and the diffusion plate 43. That is, based on the existence of this right angled triangle, a minimum value of the distance P between the virtual lines V1 and the point at which the maximum-light-intensity axis MX crosses the diffusion plate 43 is “H×tan(δ)”, where “δ” represents angle formed by the maximum-light-intensity axis MX and the virtual line V1, and “H” represents minimum distance between the light emitting points E of the LED packages PG and the diffusion plate 43.

Since the arrangement interval W for the LED packages PG is preferably equal to the distance P or shorter, the conditional expression (2) is introduced. If the conditional expression (2) is satisfied, as can be inferred from FIG. 6, it is possible to make the light beams LB overlap with each other over a wide range in the diffusion plate 43 to surely prevent the generation of dark regions.

In the foregoing descriptions, the peripheral light PL is defined as light in the light beam LB that is comparatively away from the maximum-light-intensity axis MX. Assuming that light intensity along the maximum-light-intensity axis MX is 100% light intensity as illustrated in the directional pattern diagram of FIG. 3, a specific example of the peripheral light PL is light (a light ray) having light intensity that is not higher than 30% or 50% of the light intensity along the maximum-light-intensity axis MX.

With the backlight unit 49 configured as described above, by enlarging the areas of the light beams reaching the diffusion plate 43 as in the foregoing descriptions, it is possible to reduce unevenness in brightness and chromaticity in the backlight light. It is difficult to manufacture LED packages PG without variation in light beam diameter and chromaticity at all. However, the LED packages PG configured as described above allow a wider range of variation in various factors, and thus it is easy to secure a sufficient number of operable LED packages PG, and thus to achieve an improved manufacturing yield.

The enlarged range of irradiation by each of the LED packages PG means a smaller number of LED packages PG to be used, which leads to reduction of the material cost and the number of fabrication steps in manufacturing the backlight unit 49 and the liquid crystal display device 69.

### Embodiment 2

Embodiment 2 will now be described. Members and components having similar functions as those used in Embodiment 1 are denoted with the same signs, and overlapping descriptions thereof will be omitted.

In the liquid crystal display device 69 of Example 1 illustrated, for example, in FIGS. 1 and 2, the LED package PG is supported directly on the mounting board 21, and the mounting board 21 is directly supported on the bottom surface 41B of the backlight chassis 41. In Example 1, in the LED package PG of the backlight unit 49, the support portion 13 causes the LED chip 11 to be inclined by an angle smaller than 90° with respect to the bottom surface 41B of the backlight chassis 41, to thereby incline the maximum-light-intensity axis MX by an angle smaller than 90° with respect to the diffusion plate 43 which is parallel to the bottom surface 41B. That is, a minimum angle formed by the direction in which the bottom surface 41 extends and the support portion top surface 13U of the support portion 13, and a minimum angle formed by the diffusion plate 43 and the maximum-light-intensity axis MX are both smaller than 90°.

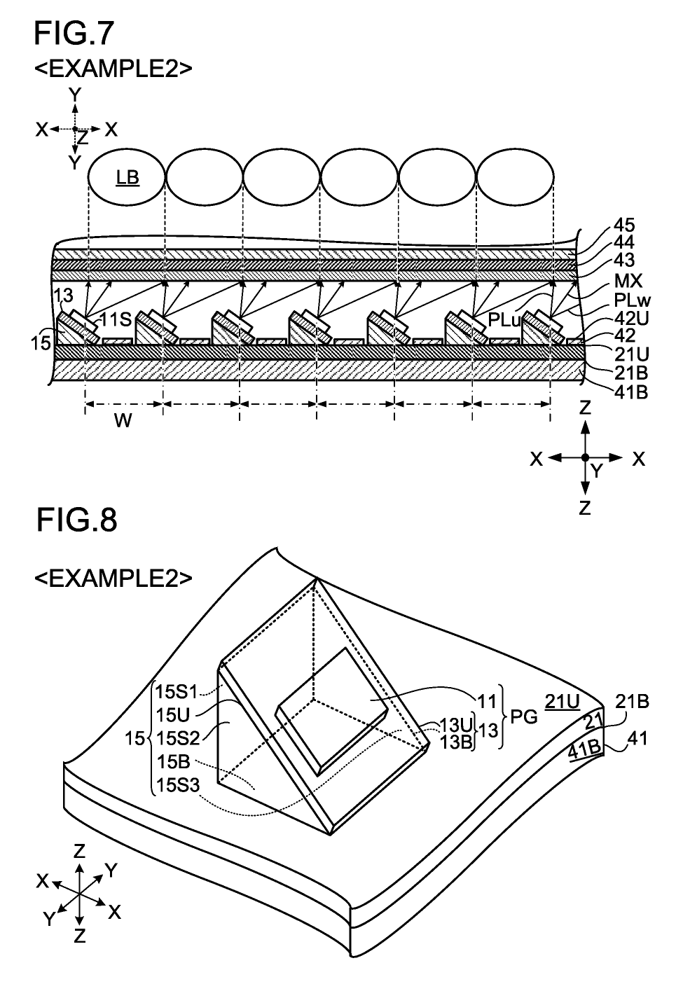

The member that causes the LED chip 11 to be inclined with respect to the bottom surface 41B of the backlight chassis 41 (such a member will be referred to as “a correction portion”) is not limited to the support portion 13 included in the LED package PG. With reference to the sectional view of FIG. 7 (taken along the same direction as FIG. 1) and the perspective view of FIG. 8 (illustrating the LED package PG, the mounting board 21, and the backlight chassis 41), a description will be given of a configuration in which a member other than the support portion 13 is used as the correction portion. A liquid crystal display device 69 and other elements illustrated in FIGS. 7 and 8 are included in Example 2.

As illustrated in FIGS. 7 and 8, in the liquid crystal display device 69 of Embodiment 2, the support portion 13 of the LED package PG is a plate. Thus, if the support portion bottom surface 3B of the support portion 13 is directly in tight contact with the mounting surface 21U of the mounting board 21, the maximum-light-intensity axis MX is perpendicular to the mounting surface 21U, and also to the bottom surface 41B of the backlight chassis 41. With such a configuration, light is not obliquely incident on the diffusion plate 43 which is parallel to the mounting surface 21U or to the bottom surface 41B of the backlight chassis 41.

To prevent this, in the backlight unit 49 of the liquid crystal display device 69 according to Example 2, although the mounting board 21 is supported directly on the backlight chassis 41 as in Example 1, the LED package PG is, in contrast to Example 1, supported indirectly on the mounting board 21. Specifically, a connection stand 15 is provided interposed between the support portion 13 of the LED package PG and the mounting board 21. That is, the connection stand 15 is included in a lighting set.

As illustrated in FIG. 8, the connection stand 15 is in tight contact with the substantially flat mounting surface 21U of the mounting board 21 and with the substantially flat support portion bottom surface 13B of the support portion 13. One surface of the connection stand 15 that is in tight contact with the mounting board 21 will be referred to as a connection stand bottom surface 15B, another surface of the connection stand 15 that is in tight contact with the support portion 13 of the LED package PG will be referred to as a connection stand top surface 15U. The connection stand 15 is built as a block that has five surfaces in total, namely, the connection stand top surface 15U, the connection stand bottom surface 15B, and in addition, three connection stand side surfaces 15S1 to 15S3 that extend rising from the mounting surface 21U of the mounting board 21.

The connection stand 15, which is built as a block, is configured such that the connection stand top surface 15U thereof is not parallel but inclined with respect to the connection stand bottom surface 15B thereof, in other words, with respect to the mounting surface of the mounting board 21, or, the bottom surface 41B of the backlight chassis 41. That is, the connection stand 15 is built as a block that is disposed such that the connection stand top surface 15U and the connection stand bottom surface 15B extend in a direction in which they cross each other.

The interposition of the connection stand 15 between the support portion 13 and the mounting board 21 makes the LED chip 11 on the support portion top surface 13U not parallel but inclined with respect to the mounting surface of the mounting board 21. Thus, light emitted from the LED package PG, especially a portion of the light corresponding to the maximum-light-intensity axis MX, is obliquely incident on the diffusion plate 43 which is positioned parallel to the bottom surface 41B of the backlight chassis 41.

As a result, the liquid crystal display device 69 and the backlight unit 49 of Example 2 also exert the same operational effects as the liquid crystal display device 69 and the backlight unit 49 described in Embodiment 1. It is preferable that the conditional expressions (1) and (2) described above be also satisfied in the liquid crystal display device 69 and the backlight unit 49 of Example 2

### Embodiment 3

Embodiment 3 will now be described. Members having similar functions as those used in Embodiments 1 and 2 are denoted with the same signs, and overlapping descriptions thereof will be omitted.

In the liquid crystal display devices 69 of Examples 1 and 2 dealt with in Embodiments 1 and 2, as illustrated in FIGS. 1 and 7, the bottom surface 41B of the backlight chassis 41 and the back surface 21B of the mounting board 21 are in tight contact with each other (it is preferable that the bottom surface 41B and the back surface 21B are flat surfaces). That is, the mounting board 21 is supported directly on the backlight chassis 41. However, this configuration is not meant as a limitation.

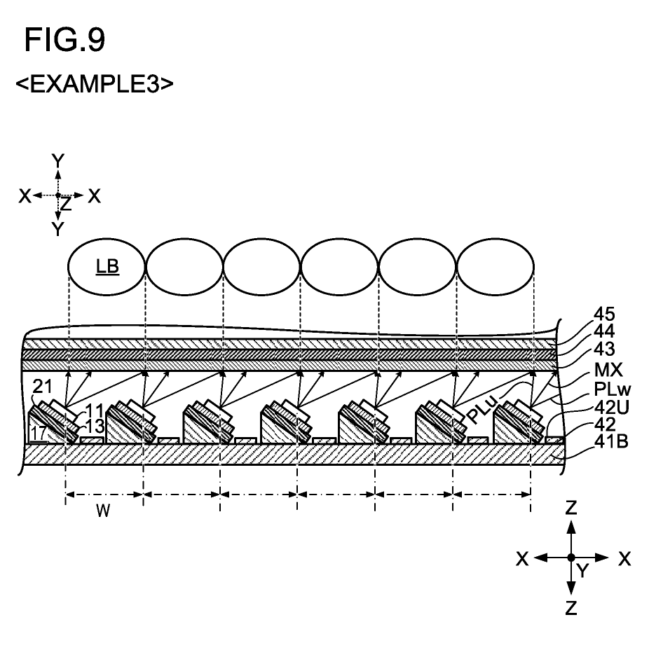

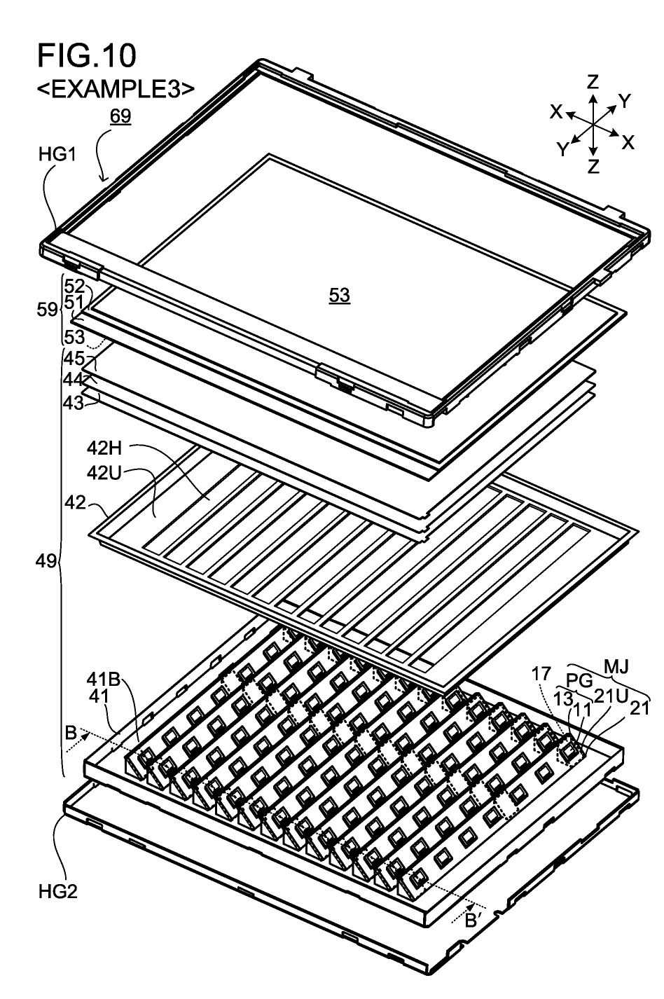

The mounting board 21 may be indirectly supported on the bottom surface 41B of the backlight chassis 41 as in a liquid crystal display device 69 illustrated in FIG. 9 (which is a sectional view taken along line B-B′ and seen as indicated by the arrows in FIG. 10) and FIG. 10. A holding stand 17 is provided interposed between the mounting board 21 and the backlight chassis 41 to function as the correction portion.

The liquid crystal display device 69 and the like illustrated in FIGS. 9 and 10 are included in Example 3, descriptions of which will be given below. In the backlight unit 49 and the liquid crystal display device 69 illustrated in these figures, the LED packages PG each include a substantially flat support portion 13 on which the LED chip 11 is directly supported. A plurality of LED packages PG are directly supported on the mounting surface 21U of the substantially flat mounting board 21 which extends in one direction (for example, direction Y), and thereby LED modules MJ are formed. The LED modules MJ are arranged in a direction that crosses the direction in which the mounting board 21 extends, that is, in direction X.

If the back surface 21B of the mounting board 21 is directly in tight contact with the bottom surface 41B of the backlight chassis 41, the maximum-light-intensity axis MX perpendicularly crosses the bottom surface 41B, and thus no light is obliquely incident on the diffusion plate 43 which is parallel to the bottom surface 41B.

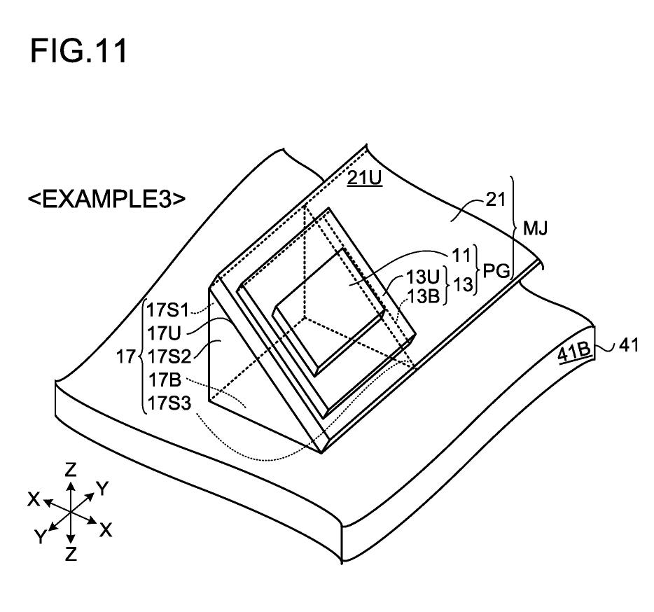

To prevent this, in each of the LED modules MJ, three holding stands 17 are placed at three positions, namely, two positions close to two opposing ends of the mounting board 21 and a position close to a center of the mounting board 21. The holding stands 17 are each in tight contact with the back surface 21B of the mounting board 21 and the bottom surface 41B of the backlight chassis 41. As illustrated in FIG. 11, in each of the holding stands 17, a surface that is in tight contact with the bottom surface 41B is a holding stand bottom surface 17B, and a surface that is in tight contact with the mounting board 21 is a holding stand top surface 17U. The holding stand 17 is built as a block having a total of five surfaces, that is, the holding stand top surface 17U, the holding stand bottom surface 17B, and in addition, three holding stand side surfaces 17S1 to 17S3 which extend rising from the bottom surface 41B.

The holding stand 17, which is built as a block, is configured such that the holding stand top surface 17U thereof is not parallel but inclined with respect to the holding stand bottom surface 17B thereof, in other words, with respect to the bottom surface 41B of the backlight chassis 41. That is, the holding stand 17 is built as a block that is disposed such that the holding stand top surface 17U and the holding stand bottom surface 17B extend in a direction in which they cross each other.

The interposition of the holding stand 17 between the mounting board 21 and the backlight chassis 41, that is, the provision of the holding stand 17 in the lighting set, makes the LED chip 11 in the LED package on the mounting board 21 not parallel but inclined with respect to the bottom surface 41B of the backlight chassis 41. Thus, light emitted from the LED package PG, especially a portion of the light corresponding to the maximum-light-intensity axis MX, is obliquely incident on the diffusion plate 43, which is positioned parallel to the bottom surface 41B of the backlight chassis 41.

As a result, the liquid crystal display device 69 and the backlight unit 49 of Example 3 also exert the same operational effects as the liquid crystal display devices 69 and the backlight units 49 described in Embodiments 1 and 2. It is preferable that the conditional expressions (1) and (2) described above be also satisfied in the liquid crystal display device 69 and the backlight unit 49 of Example 3.

The number of the holding stands 17 is not limited to three for each of the LED modules MJ. One holding stand 17 may be provided for each, or, two holding stands 17 or four or more holding stands 17 may be provided for each. As illustrated in FIG. 10, the reflection sheet 42 has holes 42H through which the LED modules MJ are exposed to the reflection surface 42U side.

### Embodiment 4

Embodiment 4 will now be described.

Members having similar functions as those used in Embodiments 1 to 3 are denoted with the same signs, and overlapping descriptions thereof will be omitted.

As to the liquid crystal display devices 69 of Examples 1 to 3 of Embodiments 1 to 3, the support portion 13 included in the LED package PG, the connection stand 15, and the holding stand 17 function as correction portions in Examples 1, 2, and 3, respectively. The correction portions incline the LED chip 11 by an angle smaller than 90° with respect to the bottom surface 41B of the backlight chassis 41, to thereby incline the maximum-light-intensity axis MX by an angle smaller than 90° with respect to the diffusion plate 43 which is parallel to the bottom surface 41B.

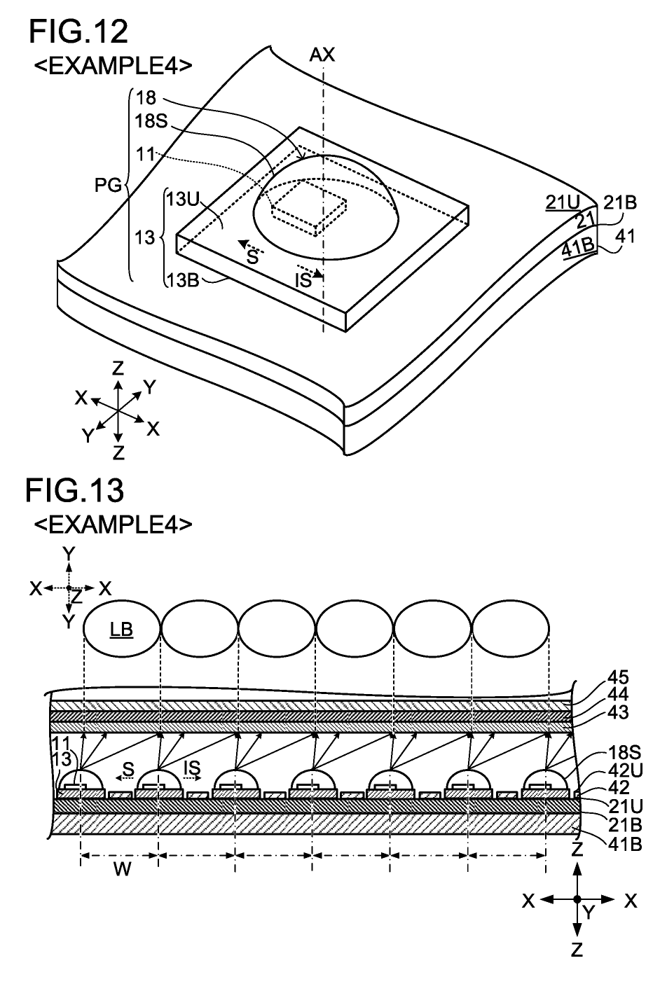

The correction portion is not limited to these correction portions. For example, as illustrated in the perspective view of FIG. 12 and the sectional view of FIG. 13 (taken in the same direction as FIG. 1), if a sealing member 18 for sealing the LED chip 11 is included in the LED package PG the sealing member 18 can serve as the correction portion.

To be more specific, in the LED package PG illustrated in FIG. 12 and FIG. 13, the sealing member 18 seals the LED chip 11 disposed on the support portion top surface 13U of the support portion 13. The sealing member 18 is made of, for example, a resin that transmits light. A surface 18S of the sealing member 18 is in contact with air, which is a medium different from the sealing member 18 itself, and thereby, the surface 18S functions as an optical surface 18S.

FIG. 12 illustrates an example in which the optical surface 18S of the sealing member 18 is hemispheric.

In the LED package PG here, the LED chip 11, which is a light source that emits light toward the optical surface 18S, is disposed to be displaced from an optical axis AX of the optical surface 18S, that is, a line AX defined by a center of curvature of the optical surface 18S and a center of a bottom surface of the sealing member 18 that is in contact with the support portion 13. In other words, the LED chip 11 and the optical surface 18S are disposed eccentric to each other.

With this configuration, light emitted from the LED chip 11 is more likely to leave the optical surface 18S in a direction (direction IS) that is opposite to a direction (direction S) in which the LED chip 11 is displaced from a position corresponding to a top of the optical surface 18S. More specifically, the light leaving the optical surface 18S, in particular, a portion thereof corresponding to the maximum-light-intensity axis MX, travels along a path that is inclined from direction IS and a direction (of the optical axis AX) perpendicular to the bottom surface 41B of the backlight chassis 41. That is, with the sealing member 18 which is a light transmitting member and has the optical surface 18S, the optical surface 18S causes the maximum-light-intensity axis MX, along which the light emitted from the LED chip 11 is most intense, to be inclined toward the bottom surface 41B of the backlight chassis 41.

Light passing through the sealing member 18 to travel in various directions, especially a portion of the light corresponding to the maximum-light-intensity axis MX, is obliquely incident on the diffusion plate 43, which is positioned parallel to the bottom surface 41B of the backlight chassis 41. As a result, the liquid crystal display device 69 of Example 4 illustrated in FIG. 12 and FIG. 13 also exerts the same operational effects as the liquid crystal display devices 69 and the backlight units 49 described in Embodiments 1 to 3. It is preferable that the conditional expressions (1) and (2) described above be also satisfied in the liquid crystal display device 69 and the backlight unit 49 of Example 4.

The shape of the optical surface 18S of the sealing member 18 is not limited to the hemispheric shape as illustrated in FIG. 12 and FIG. 13. Furthermore, the position of the LED chip 11 is not limited to a position displaced from the optical axis AX of the optical surface 18S.

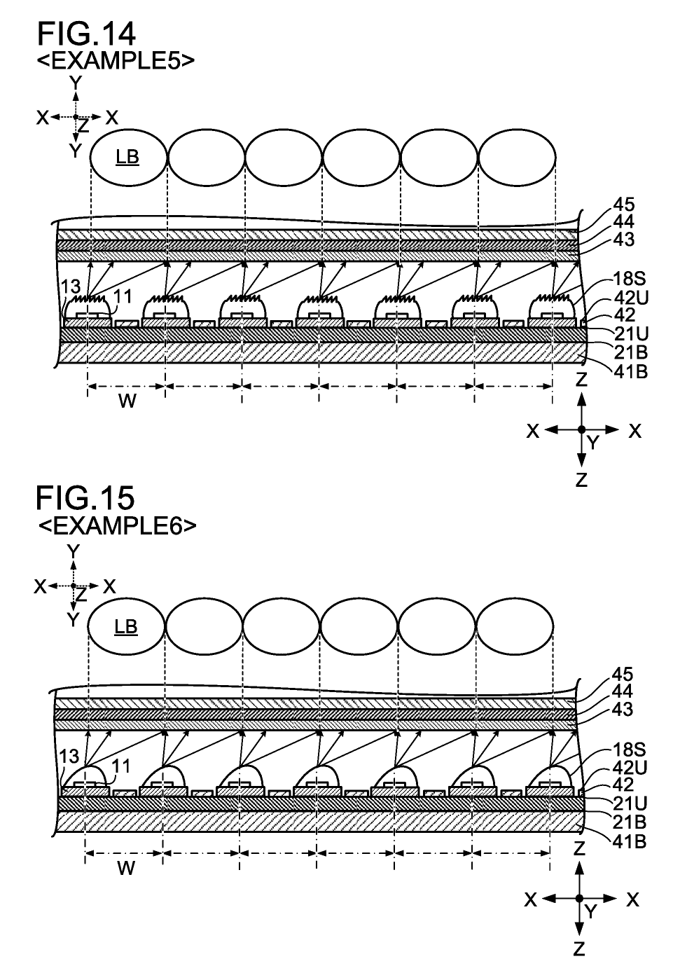

For example, as illustrated in the sectional view of FIG. 14 illustrating Example 5, the optical surface 18S of the sealing member 18 may have a saw-toothed sectional shape so that the sealing member 18 performs a function of a Fresnel lens. Alternatively, as illustrated in the sectional view of FIG. 15 illustrating Example 6, the optical surface 18S of the sealing member 18 may include a portion having a curvature that is smaller or larger than that of the other portions. That is, the optical surface 18S may be a free-form surface including a portion that is different from the other portions in curvature.

In Examples 5 and 6 as well, light passing through the sealing member 18 to travel in various directions, especially a portion of the light corresponding to the maximum-light-intensity axis MX, is obliquely incident on the diffusion plate 43 that is positioned parallel to the bottom surface 41B of the backlight chassis 41. As a result, the liquid crystal display devices 69 of Examples 5 and 6 also exert the same operational effects as exerted in Example 4. In Examples 5 and 6, the LED chip 11 is positioned overlapping the optical axis AX, but this is not meant as a limitation. The LED chip 11 may be displaced with respect to the optical axis AX.

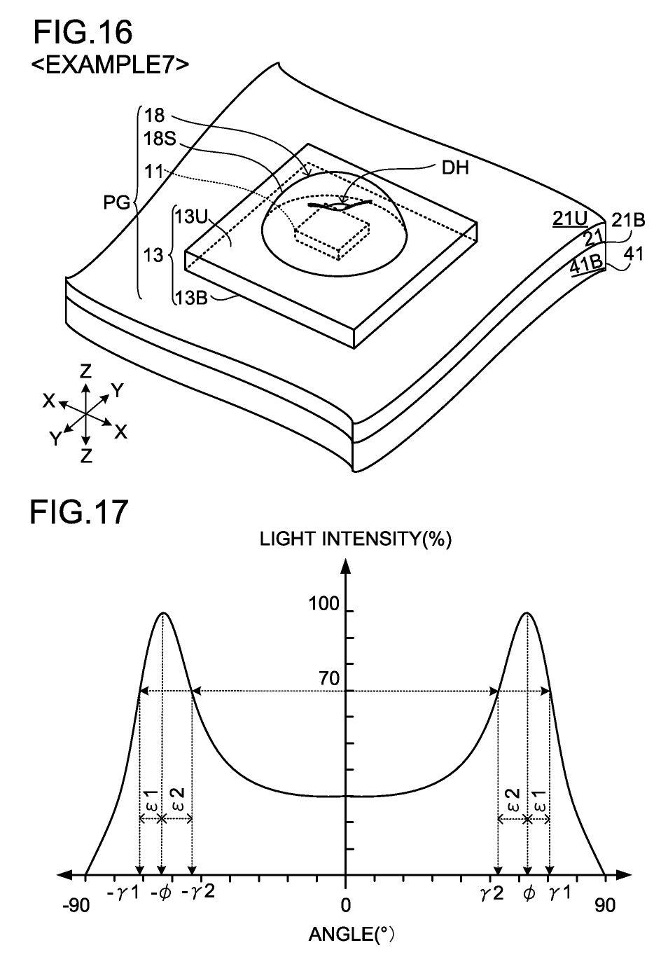

As illustrated in the perspective view of FIG. 16 illustrating Example 7, in the optical surface 18S of the sealing member 18, a depression may be formed right above the LED chip 11. In other words, a depression DH may be formed in the optical surface 18S. With the LED package PG having such a configuration, when light from the LED chip 11 is supplied to the sealing member 18 including the depression DH formed in the optical surface 18S, the light leaves the sealing member 28 in a directional pattern as illustrated in FIG. 17.

That is, a portion of the light traveling directly upward from the LED chip 11 (light at an angle 0°) has a relatively low light intensity, while portions of the light traveling in directions inclined with respect to the direction directly upward from the LED chip 11 have a maximum light intensity. That is, the maximum-light-intensity axis MX in the light from the LED package PG is inclined with respect to the direction directly upward from the LED chip 11.

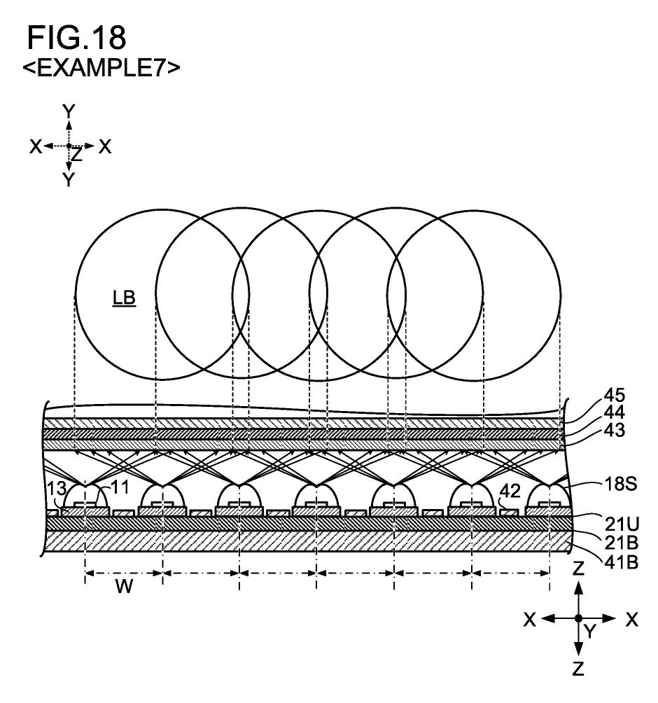

As illustrated in the sectional view of FIG. 18 (taken along the same direction as FIG. 1), light passing through the sealing member 18 to travel in various directions, especially a portion of the light corresponding to the maximum-light-intensity axis MX, is obliquely incident on the diffusion plate 43 that is positioned parallel to the bottom surface 41B of the backlight chassis 41. As a result, the liquid crystal display device 69 of Example 7 also exerts the same operational effects as those in Examples 4 to 6.

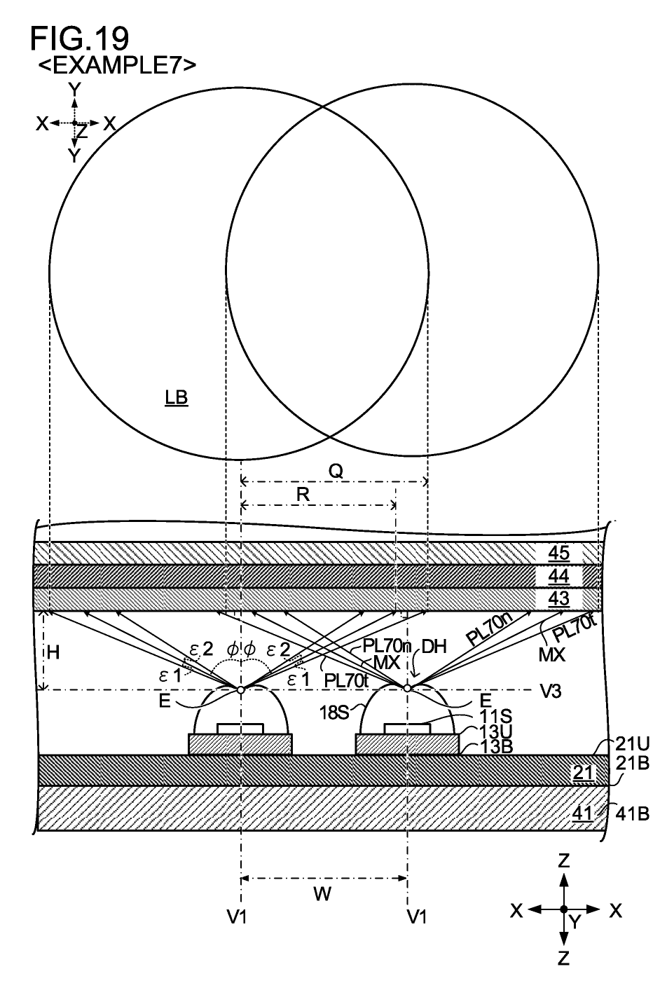

As illustrated in the directional pattern diagram of FIG. 17, an angle φ, at which light intensity is maximum, appears at two positions in a particular cross-section, that is, the maximum light intensity is observed at angles of ±φ in the directional pattern diagram. That is, two maximum-light-intensity axes MX appear as illustrated in FIG. 19, which is an enlarged view of FIG. 18, and the two maximum-light-intensity axes MX are each inclined by an angle of φ with respect to the direction directly upward from the LED chip 11. From FIG. 17, 70%-light-intensity portions of light having light intensity of 70% of the maximum light intensity, for example, exist on a side farther away (more inclined) from the direction directly upward from the LED chip 11 than each of the maximum-light-intensity axes MX, and on a side closer to (less inclined from) the direction directly upward from the LED chip 11 than each of the maximum-light-intensity axes MX.

Assume that, as shown in FIG. 17, with respect to each of the maximum-light-intensity axes MX, the size of an angle formed between the maximum-light-intensity axis MX and the 70%-light-intensity portion of the light on the side farther away (more inclined) from the direction directly upward from the LED chip 11 than the maximum-light-intensity axis MX is “ε1”, and the size of an angle formed between the maximum-light-intensity axis MX and the 70%-light-intensity portion of the light on the side closer to (less inclined from) the direction directly upward from the LED chip 11 than the maximum-light-intensity axis MX is “ε2”. Furthermore, assume that angles indicated on the lateral axis in FIG. 17 that correspond to the portions of the light forming the angles of “ε1” and “ε2” are “γ1” and “γ2”, respectively. It is preferable that the following conditional expression (3) be satisfied in the liquid crystal display device 69 of Example 7.

W≦H×tan(γ1) conditional expression (3)

where

W represents interval at which light source packages are arranged;

H represents minimum distance from a light emitting point in each of the light source packages to the diffusion plate; and

γ1 represents, assuming that the maximum light intensity of the light passing through the sealing member is 100% light intensity, and that an angle of the direction directly upward from the light emitting chip is 0°, in a cross-section taken along a light-source-package arrangement direction, an angle that one of the 70%-light-intensity portions of the light passing through the sealing member that most diverges from the direction directly upward from the light emitting chip has with respect to the direction directly upward from the light emitting chip (that is, γ1=φ+ε1).

Descriptions will be given with reference to FIG. 17 and FIG. 19. In FIG. 19, among the 70%-light-intensity portions of the light, those traveling farther away from the direction directly upward from the LED chip 11 than the maximum-light-intensity axis MX are indicated as peripheral light PL70t, and those travelling closer to the direction directly upward from the LED chip 11 than the maximum-light-intensity axis MX are indicated as peripheral light PL70n. An angle formed between the maximum-light-intensity axis MX and the peripheral light PL70t is “ε1”, and an angle formed between the maximum-light-intensity axis MX and the peripheral light PL70n is “ε2”.

Assume that a shape defined by the peripheral light PL70t, one of virtual lines V1, and the diffusion plate 43 is a right angled triangle having a right angle formed by the virtual line V1 and the diffusion plate 43. In this case, a minimum distance Q from a point at which the peripheral light PL70t crosses the diffusion plate 43 and the virtual line V1, which includes the light emitting point E of one of the LED packages PG, is “H×tan(γ1), from the angle (γ1=φ+ε1) between the peripheral light PL70t and the virtual line V1 and the minimum distance H between the light emitting point E of the LED package PG and the diffusion plate 43. As illustrated in FIG. 19, the distance Q is preferably shorter than the arrangement interval W at which the LED packages PG are arranged, and thus the conditional expression (3) is introduced.

Experiments were actually conducted to measure uneven distribution of light quantity with a liquid crystal display device 69 where the conditional expression (3) is satisfied (interval W=85 mm); uneven distribution of light quantity was observed to some extent when the liquid crystal display panel 59 displayed a single-color image (a solid image), but uneven distribution of light quantity was not observed at all when the liquid crystal display panel 59 displayed a moving image. A specific example of the experiments is as follows: φ=65°, ε1=10°, H=25 mm, and therefore, W≦25×tan(65°±10°)=93.3 mm

Light having light intensity of 70% of the maximum light intensity is dealt with in the conditional expression (3), but this is not meant as a limitation. Even with light having light intensity of 50% or 30% of the maximum light intensity, for example, it is possible to reduce uneven distribution of light quantity.

To securely reduce uneven distribution of light quantity in a solid image as well, it is preferable to satisfy the following conditional expression (4).

W≦H×tan(φ) conditional expression (4)

where

W represents arrangement interval for the light source packages;

H represents minimum distance from the light emitting point in each of the light source packages to the diffusion plate; and

φ represents, assuming that an angle of the direction directly upward from the light emitting chip is 0°, an angle that the maximum-light-intensity axis, along which the light passing through the sealing member has the maximum light intensity, has with respect to the direction directly upward from the light emitting chip, in a cross-section taken along a light-source-package arrangement direction.

The conditional expression (4) is obtained based on the fact that the shape defined by the maximum-light-intensity axis MX, the diffusion plate 43, and the virtual line V1 is a right angled triangle having a right angle formed by the virtual line V1 and the diffusion plate 43. That is, a minimum distance R from the point at which the maximum-light-intensity axis MX crosses the diffusion plate 43 to the virtual line V1 which includes the light emitting point E through which the maximum-light-intensity axis MX passes is “H×tan φ”, where “φ” represents angle formed by the maximum-light-intensity axis MX and the virtual line V1, and H represents minimum distance from the light emitting point E of the LED package PB to the diffusion plate 43. As illustrated in FIG. 19, the distance R is preferably shorter than the arrangement interval W of the LED packages PG are arranged, and thus the conditional expression (4) is introduced.

Experiments were actually conducted to measure uneven distribution of light quantity with a liquid crystal display device 69 where the conditional expression (4) is satisfied (the interval W=50 mm); uneven distribution of light quantity was not observed even when the liquid crystal display panel 59 displayed a solid image. Moreover, in a case where LED packages PG of different colors were arranged side by side, by increasing the extent of color mixture, that is, by increasing the area over which the light beams LB overlap with each other, even color unevenness was reduced. A specific example of the experiments is as follows: φ=65°, H=25 mm, and therefore, W≦25×tan)(65°)=53.6 mm

In any one of Embodiments 1 to 4, if the number of the LED packages PG in the liquid crystal display device 69 is reduced within an allowable range of display unevenness, to achieve a required screen brightness and a required display quality in the liquid crystal display device 69, each of the LED packages PG in the backlight unit 49 needs to be ensured to be able to output a light beam of a sufficient beam diameter, and the light beams outputted from the LED packages PG need to be distributed all over the liquid crystal display panel 59.

Assume that, for example, in a liquid crystal display device 69 whose active area size is 885 mm (width)×498 mm (height) (40-inch type), the angle φ in each LED package PG including a sealing member 18 having the depression DH is 65°. Assume also that the LED chip in each LED package PG has a quadrangular shape whose sides are each 500 nm long, and thus a light emitting region thereof has an area of 0.25 mm². In a case in which eighteen LED packages PG were arranged in the width direction at intervals of 45 mm and nine LED packages PG were arranged in the height direction at intervals of 45 mm, the above-described requirements were satisfied when a diffusion plate 43, a diffusion sheet, a prism sheet, and a polarization-reflection sheet (DBEF by Sumitomo 3M Co., Ltd.) were used as optical sheets, and the distance between each LED light emitting point and the diffusion plate was set to 25 mm

That is, a liquid crystal display panel 59 was achieved in which required screen brightness was ensured with uniform and comfortable distribution of brightness from the center to the edges of the screen. Moreover, in the liquid crystal display device 69, brightness unevenness and chromaticity unevenness corresponding to each of the LED packages PG were able to be reduced with a reduced number of LED packages PG.

In the directional pattern in the particular cross-section as illustrated in FIG. 17, the maximum light intensity (a peak) appears at angles of ±φ. However, the directional pattern illustrated in FIG. 17 is not meant as a limitation, and the maximum light intensity may appear at more than two positions in the directional pattern. For example, in FIG. 17, the maximum light intensity can also appear at a position or positions within a range between the two peaks of the maximum light intensity, for example, in the vicinity of right above the LED chip 11, or in the vicinity of the two positions of the maximum light intensity. The conditional expressions (3) and (4) are applicable to such cases, too.

In addition to the maximum light intensity, there may exist light intensity having a local maximum value (a maximal value). For example, in FIG. 17, in the range between the two peaks of the maximum light intensity, there may be one or a plurality of peaks at which light intensity has a value that is lower than that of the maximum light intensity but is the locally highest (maximal) in the range. In FIG. 17, in an angular range between φ and 90° or in an angular range between −φ and −90°, there may be one or a plurality of peaks at which light intensity has a value that is lower than that of the maximum light intensity but is the locally highest (maximal) in the range.

### Other Embodiments

It should be understood that the embodiments specifically described hereinbefore are not meant to limit the present invention and that many variations and modifications can be made within the spirit of the present invention.

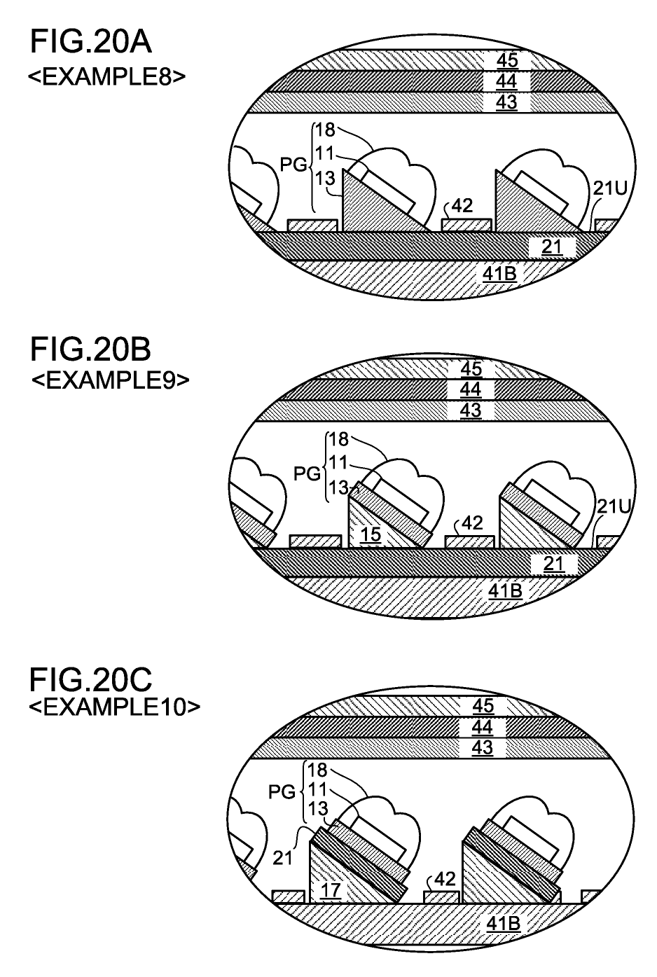

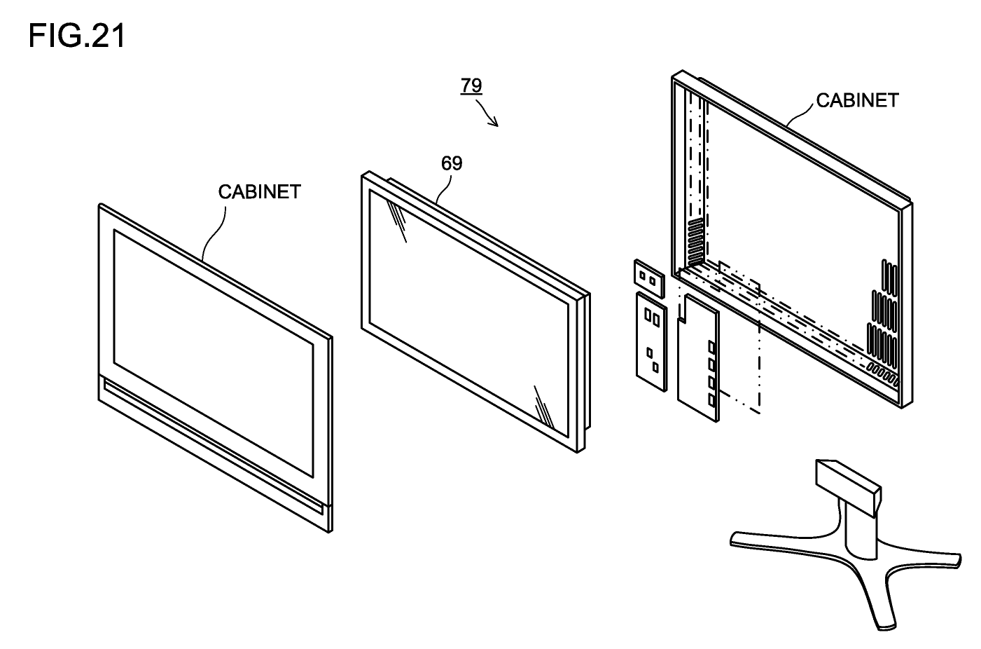

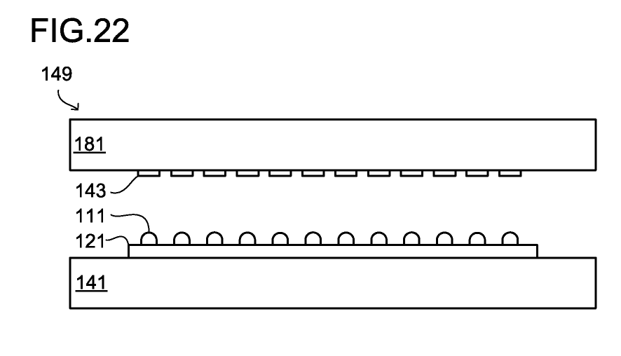

For example, the sealing member 18 described in Embodiment 4 may be added to the LED package PG of any one of Examples 1 to 3 in Embodiments 1 to 3. For example, as illustrated in FIG. 20A, a liquid crystal display device 69 of Example 8 may be configured by adding the sealing member 18 of Example 7 (see FIG. 18) to the LED package PG of Example 1 (see FIG. 1).

That is, the LED package PG includes the sealing member 18 having the depression DH in its optical surface 18S, the LED package PG is directly supported on the mounting board 21, and the mounting board 21 is directly supported on the bottom surface 41B of the backlight chassis 41. The support portion 13 of the LED package PG is built as a block having a shape in which the support portion top surface 13U and the support portion bottom surface 13B extend in the direction in which they cross each other. The support portion 13, together with the sealing member 18, causes the maximum-light-intensity axis MX of light passing through the sealing member 18 to be inclined with respect to the bottom surface of the backlight chassis 41.

Furthermore, for example, as illustrated in FIG. 20B, a liquid crystal display device 69 of Example 9 may be configured by adding the sealing member 18 of Example 7 (see FIG. 18) to the LED package PG of Example 2 (see FIG. 7).

That is, the LED package PG includes the sealing member 18 having the depression DH in its optical surface 18S is supported indirectly on the mounting board 21, and the mounting board 21 is directly supported on the bottom surface 41B of the backlight chassis 41. The connection stand 15 is provided interposed between the support portion 13 of the LED package PG and the mounting board 21. The connection stand 15 is built as a block having a shape in which the connection stand top surface 15U and the connection stand bottom surface 15B extend in the direction in which they cross each other. The connection stand 15, together with the sealing member 18, causes the maximum-light-intensity axis MX of light passing through the sealing member 18 to be inclined with respect to the bottom surface of the backlight chassis 41.

Moreover, for example, as illustrated in FIG. 20C, a liquid crystal display device 69 of Example 10 may be configured by adding the sealing member 18 of Example 7 (see FIG. 18) to the LED package PG of Example 3 (see FIG. 9).

That is, the LED package PG includes the sealing member 18 having the depression DH in its optical surface 18S is supported directly on the mounting board 21, and the mounting board 21 is directly supported on the bottom surface 41B of the backlight chassis 41. The holding stand 17 is provided interposed between the mounting board 21 and the bottom surface 41B of the backlight chassis 41. The holding stand 17 is built as a block having a shape in which the holding stand top surface 17U and the holding stand bottom surface 17B extend in the direction in which they cross each other. The holding stand 17, together with the sealing member 18, causes the maximum-light-intensity axis MX of light passing through the sealing member 18 to be inclined with respect to the bottom surface of the backlight chassis 41.

Examples 8 to 10 deal with the sealing member 18 of Example 7 as an example of the sealing member 18, but this is not meant as a limitation. For example, the sealing member 18 of any of Examples 4 to 6 may be used in Examples 8 to 10 as the sealing member 18.

The color of light emitted from the LED package PG is not limited to any specific color. For example, the color may be red, green, blue, or white. A configuration may be adopted in which the LED package PG has a fluorescent substance built-in, and the sealing member 18, for example, contains a fluorescent substance, such that white light is generate by mixing light from the LED chip 11 and light generated by fluorescence when the sealing member 18 receives light from the LED chip 11.

A specific example of such a configuration is one in which the LED package PG includes a blue-light-emitting LED chip 11 or an ultraviolet-light-emitting LED chip 11 and a fluorescent substance which emits yellow light by fluorescence on receiving light from the LED chip 11. The thus-configured LED package PG generates white light by mixing the light from the LED chip 11 which emits blue or ultraviolet light and the light generated by fluorescence.

The fluorescent substance provided in the LED package PG is not limited to one that emits yellow light by fluorescence. The LED package PG may be configured to include a blue-light-emitting LED chip 11 and a fluorescent substance that emits green and red light by fluorescence on receiving light from the LED chip 11, such that white light is generated from the blue light from the LED chip 11 and the green and red light generated by fluorescence.

The LED chip 11 provided in the LED package PG is not limited to one that emits blue light. In the LED package PG, a plurality of LED chips 11 may be disposed on the support portion 13, the plurality of LED chips 11 including a red-light-emitting LED chip 11 and a blue-light-emitting LED chip 11, and further, a fluorescent substance that emits green light generated by fluorescence on receiving light from the blue-light-emitting LED chip 11 may also be included. In the thus-configured LED package, white light is generated from the red light from the red-light-emitting LED chip 11, the blue light from the blue-light-emitting LED chip 11, and the green light generated by fluorescence.

Such an LED package PG may be adopted that includes no fluorescent substance. For example, the LED package PG may be one in which a plurality of LED chips are disposed on the support portion 13, the plurality of LED chips including a red-light-emitting LED chip 11, a green-light-emitting LED chip 11, and a blue-light-emitting LED chip 11, so that white light is generated from light emitted from all the LED chips 11.

### LIST OF REFERENCE SYMBOLS

PG LED package (light source package)
11 LED chip (light emitting chip)
11S light emitting surface of LED chip
11B bottom surface of LED chip
13 support portion
13U support portion top surface
13B support portion bottom surface
15 connection stand
15U connection stand top surface
15B connection stand bottom surface
17 holding stand
17U holding stand top surface
17B holding stand bottom surface
18 sealing member
18S optical surface
21 mounting board
21U mounting surface
21B rear surface
MJ LED module (light source module)
41 backlight chassis
41B backlight chassis bottom surface (without a base)
MX maximum-light-intensity axis
AX optical axis
PL peripheral light
49 backlight unit (lighting device)
59 liquid crystal display panel (display panel)
69 liquid crystal display device (display device)
79 liquid crystal television set

1. A lighting set, comprising:
a light source package having a light emitting chip and a support portion on which the light emitting chip is supported;
a mounting board on which the light source package is supported in either one of a direct manner and an indirect manner; and
a base plate on which the mounting board is supported in either one of a direct manner and an indirect manner,
wherein
the lighting set further comprises a correction portion which causes the light emitting chip to be inclined, to thereby cause a maximum-light-intensity axis, along which light from the light source package has maximum light intensity, to be inclined with respect to the base plate.

2. The lighting set according to claim 1,
wherein,
in a case in which the light source package is supported directly on the mounting board and the mounting board is supported directly on the base plate,
the support portion serves as the correction portion, the support portion being built as a block having a support portion top surface which is in contact with the light emitting chip and a support portion bottom surface which is in contact with the base plate, the support portion top surface and the support portion bottom surface extending in crossing directions.

3. The lighting set according to claim 1,
wherein,
in a case in which the light source package is supported indirectly on the mounting board and the mounting board is supported directly on the base plate,
a connection stand provided interposed between the support portion and the mounting board serves as the correction portion, the connection stand being built as a block having a connection stand top surface which is in contact with the support portion and the connection stand bottom surface which is in contact with the mounting board, the connection stand top surface and the connection stand bottom surface extending in crossing directions.

4. The lighting set according to claim 1,
wherein,
in a case in which the light source package is supported directly on the mounting board and the mounting board is supported indirectly on the base plate,
a holding stand provided interposed between the mounting board and the base plate serves as the correction portion, the holding stand being built as a block having a holding stand top surface which is in contact with the mounting board and a holding stand bottom surface which is in contact with the base plate, the holding stand top surface and the holding stand bottom surface extending in crossing directions.

5. A lighting device, comprising:
the lighting set according to claim 1; and
a diffusion plate which receives light from the lighting set,
wherein
a minimum angle of the maximum-light-intensity axis with respect to the diffusion plate is smaller than 90°.

6. The lighting device according to claim 5,
wherein the following conditional expression (1) is satisfied:
W≦H×{tan(δ+θ)−tan(δ−θ)} conditional expression (1)
where
W represents arrangement interval for the light source package;
H represents minimum distance from a light emitting point in the light source package to the diffusion plate;
δ represents angle that a light emitting surface of the light emitting chip has with respect to the base plate, in a plane where a locus of movement of the maximum-light-intensity axis resulting from inclination of the light source package is able to be grasped as a plane; and
θ represents angle formed, in the plane where the locus of movement of the maximum-light-intensity axis resulting from inclination of the light source package is able to be grasped as a plane, by the maximum-light-intensity axis and one portion of peripheral portions of light from the light source package which surround the maximum-light-intensity axis, the one portion being inclined to be the closest to the base plate of all the peripheral portions of the light from the light source package.

7. The lighting device according to claim 5,
wherein
the following conditional expression (2) is satisfied:
W≦H×tan δ conditional expression (2)
where
W represents arrangement interval for the light source package;
H represents minimum distance from a light emitting point in the light source package to the diffusion plate; and
δ represents angle that a light emitting surface of the light emitting chip has with respect to the base plate, in a plane where a locus of movement of the maximum-light-intensity axis resulting from inclination of the light source package is able to be grasped as a plane.

8. The lighting device according to claim 6,
wherein,
assuming that light intensity corresponding to the maximum-light-intensity axis is 100% light intensity, light intensity of the peripheral portions of the light from the light source package is not higher than 30% of the light intensity corresponding to the maximum-light-intensity axis.

9. The lighting device according to claim 6,
wherein,
assuming that light intensity corresponding to the maximum-light-intensity axis is 100% light intensity, light intensity of the peripheral portions of the light from the light source package is not higher than 50% of the light intensity corresponding to the maximum-light-intensity axis.

10. The lighting device according to claim 7,
wherein,
assuming that light intensity corresponding to the maximum-light-intensity axis is 100% light intensity, light intensity of the peripheral portions of the light from the light source package is not higher than 30% of the light intensity corresponding to the maximum-light-intensity axis.

11. The lighting device according to claim 7,
wherein,
assuming that light intensity corresponding to the maximum-light-intensity axis is 100% light intensity, light intensity of the peripheral portions of the light from the light source package is not higher than 50% of the light intensity corresponding to the maximum-light-intensity axis.

12. A lighting set, comprising:
a light source package which comprises a light emitting chip, a support portion on which the light emitting chip is supported, and a sealing member which seals the light emitting chip; a mounting board on which the light source package is supported in either one of a direct manner and an indirect manner; and
a base plate on which the mounting board is supported in either one of a direct manner and an indirect manner,
wherein
the sealing member transmits light and has an optical surface, and, by using the optical surface, functions as a correction portion which causes a maximum-light-intensity axis, along which light passing through the sealing member has maximum light intensity, to be inclined with respect to the base plate.

13. The lighting set according to claim 12,
wherein
the optical surface and the light emitting chip are positioned eccentric to each other.

14. The lighting set according to claim 12,
wherein
the sealing member functions as a Fresnel lens.

15. The lighting set according to claim 12,
wherein
the optical surface includes a portion that is different in curvature from the other portions of the optical surface.

16. The lighting set according to claim 12,
wherein
a portion of the optical surface located right above the light emitting chip is depressed in comparison with portions therearound.

17. The lighting set according to claim 12,
wherein,
in a case in which the light source package is supported directly on the mounting board and the mounting board is supported directly on the base plate,
the support portion is built as a block having a support portion top surface which is in contact with the light emitting chip and a support portion bottom surface which is in contact with the base plate, and the support portion functions as a correction portion which causes a maximum-light-intensity axis, along which light passing through the sealing member has maximum light intensity, to be inclined with respect to the base plate.

18. The lighting set according to claim 12,
wherein,
in a case in which the light source package is supported indirectly on the mounting board and the mounting board is supported directly on the base plate, a connection stand is provided interposed between the support portion and the mounting board; and
the connection stand is built as a block having a connection stand top surface which is in contact with the support portion and a connection stand bottom surface which is in contact with the mounting board, the connection stand top surface and the connection stand bottom surface extending in crossing directions, and the connection stand functions as a correction portion which causes a maximum-light-intensity axis, along which light passing through the sealing member has maximum light intensity, to be inclined with respect to the base plate.

19. The lighting set according to claim 12,
wherein,
in a case in which the light source package is supported directly on the mounting board, and the mounting board is supported indirectly on the base plate,
a holding stand is provided interposed between the mounting board and the base plate, and
the holding stand is built as a block having a holding stand top surface which is in contact with the mounting board and a holding stand bottom surface which is in contact with the base plate, the holding stand top surface and the holding stand bottom surface extending in crossing directions, and the holding stand functions as a correction portion which causes a maximum-light-intensity axis, along which light passing through the sealing member has maximum light intensity, to be inclined with respect to the base plate.

20. A lighting device, comprising:
the lighting set according to claim 12; and
a diffusion plate which receives light from the lighting set,
wherein
a minimum angle of the maximum-light-intensity axis with respect to the diffusion plate is smaller than 90°.

21. A lighting device, comprising:
the lighting set according to claim 16; and
a diffusion plate which receives light from the lighting set,
wherein
the following conditional expression (3) is satisfied:
W≦H×tan(γ1) conditional expression (3)
where
W represents arrangement interval for the light source package;
H represents minimum distance from a light emitting point in the light source package to the diffusion plate; and
γ1 represent, assuming that the maximum light intensity of light passing through the sealing member is 100% light intensity and that an angle of the direction directly upward from the light emitting chip is 0°, an angle of one portion of 70%-light-intensity portions of the light passing through the sealing member, the one portion being the most diverged of all the 70%-light-intensity portions from the direction directly upward from the light emitting chip, with respect to the direction directly upward from the light emitting chip, in a cross-section taken along a light-source-package arrangement direction.

22. A lighting device, comprising:
the lighting set according to claim 16; and
a diffusion plate which receives light from the lighting set, wherein the following conditional expression (4) is satisfied:
W≦H×tan(φ) conditional expression (4)
where
W represents arrangement interval for the light source package;
H represents minimum distance from a light emitting point in the light source package to the diffusion plate; and
φ represents, assuming that an angle of the direction directly upward from the light emitting chip is 0°, an angle that the maximum-light-intensity axis, along which the light passing through the sealing member has maximum light intensity, has with respect to the direction directly upward from the light emitting chip, in a cross-section taken along a light-source-package arrangement direction.

23. A display device, comprising:
the lighting device according to claim 5; and
a display panel which receives light from the lighting device.

24. The display device according to claim 23,
wherein
the display panel is a liquid crystal display panel.

25. A display device, comprising:
the lighting device according to claim 20; and
a display panel which receives light from the lighting device.

26. The display device according to claim 25,
wherein
the display panel is a liquid crystal display panel.
